(19) United States
(12) Patent Application Publication
(10) Pub. No.: US 2018/0143258 A1
(43) Pub. Date: May 24, 2018

(54) METHOD AND APPARATUS FOR ESTIMATING BATTERY STATE

(71) Applicant: SAMSUNG ELECTRONICS CO., LTD., Suwon-si (KR)

(72) Inventors: Sungick KIM, Seoul (KR); Tae Won SONG, Yongin-si (KR)

(73) Assignee: SAMSUNG ELECTRONICS CO., LTD., Suwon-si (KR)

(21) Appl. No.: 15/687,842

(22) Filed: Aug. 28, 2017

(30) Foreign Application Priority Data
Nov. 23, 2016 (KR) 10-2016-0156763

(51) Int. Cl. G01R 31/36; H01M 10/48

(52) U.S. Cl. CPC G01R 31/3651; H01M 10/48; G01R 31/3658; G01R 31/3606

(57) ABSTRACT

A battery state estimation method includes acquiring states of charge (SOCs) of cells of a battery, and determining whether the SOCs are within an SOC range defined as a range greater than a lower limit SOC and less than an upper limit SOC, and estimating a representative SOC of the battery from at least one of the SOCs.

### CROSS-REFERENCE TO RELATED APPLICATIONS

This application claims the benefit under 35 USC § 119(a) of Korean Patent Application No. 10-2016-0156763 filed on Nov. 23, 2016 in the Korean Intellectual Property Office, the entire disclosure of which is incorporated herein by reference for all purposes.

### BACKGROUND

### 1. Field

The following description relates to technology for estimating a battery state.

### 2. Description of Related Art

A battery is used as a power source of, for example, a mobile device, an electric vehicle, etc. A need for advanced battery control technology has been growing with an increasing number of persons using an electric vehicle or a mobile device to which a battery is mounted. An accurate state of a battery needs to be estimated to control the battery. In response to an occurrence of an error in estimating the state of the battery, an error may occur in information that is used as a standard to control the battery.

A state of charge (SOC) of a cell of the battery may be used to estimate the state of the battery. A relative great SOC deviation between cells may cause an error in estimating an SOC of the battery. If the SOC of the battery is inaccurately estimated, the battery may be exposed to over-discharging or overcharging, or may be used within a risk range. Battery state estimation technology is required to safely control the battery.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a battery state estimation method includes acquiring states of charge (SOCs) of cells of a battery, and determining whether the SOCs are within an SOC range defined as a range greater than a lower limit SOC and less than an upper limit SOC, and estimating a representative SOC of the battery from at least one of the SOCs.

The estimating may include estimating the representative SOC based on lower SOCs of a predetermined ratio, among the SOCs, in response to at least one of the SOCs being less than the lower limit SOC.

The estimating based on the lower SOCs may include generating a weight for estimating the representative SOC based on any one or any combination of a statistical characteristic of the SOCs, a statistical characteristic of temperatures of the cells, and a representative value of the lower SOCs, and estimating the representative SOC by applying the weight to a maximum SOC and a minimum SOC among the SOCs.

The estimating may include estimating the representative SOC based on upper SOCs of a predetermined ratio, among the SOCs, in response to at least one of the SOCs being greater than the upper limit SOC.

The estimating based on the upper SOCs may include generating a weight for estimating the representative SOC based on any one or any combination of a statistical characteristic of the SOCs, a statistical characteristic of temperatures of the cells, and a representative value of the upper SOCs, and estimating the representative SOC by applying the weight to a maximum SOC and a minimum SOC among the SOCs.

The estimating may include determining whether the battery is in a discharging state, a rest state, or a charging state, in response to the SOCs being within the SOC range, generating a weight for estimating the representative SOC based on a result of the determining, and estimating the representative SOC by applying the weight to a maximum SOC and a minimum SOC among the SOCs.

The generating may include generating the weight based on any one or any combination of a statistical characteristic of the SOCs, a statistical characteristic of temperatures of the cells, and a representative value of lower SOCs of a predetermined ratio, among the SOCs, in response to the battery being in the discharging state.

The generating may include generating the weight based on any one or any combination of a statistical characteristic of the SOCs, a statistical characteristic of temperatures of the cells, and a representative value of the SOCs, in response to the battery being in the rest state.

The generating may include generating the weight based on any one or any combination of a statistical characteristic of the SOCs, a statistical characteristic of temperatures of the cells, and a representative value of upper SOCs of a predetermined ratio, among the SOCs, in response to the battery being in the charging state.

The estimating may include detecting a malfunction of the battery in response to at least one of the SOCs being greater than the upper limit SOC and at least one of the SOCs being less than the lower limit SOC.

In another general aspect, a battery state estimation method includes acquiring SOCs of cells of a battery, acquiring temperatures of the cells, generating a weight for estimating a representative SOC of the battery based on any one or any combination of a statistical characteristic of the SOCs and a statistical characteristic of the temperatures, and estimating the representative SOC based on the SOCs and the weight.

The statistical characteristic of the SOCs may include a standard deviation of the SOCs, and the statistical characteristic of the temperatures may include a standard deviation of the temperatures.

In another general aspect, a battery state estimation apparatus includes a processor configured to acquire SOCs of cells of a battery, and to determine whether the SOCs are within an SOC range defined as a range greater than a lower limit SOC and less than an upper limit SOC, and estimate a representative SOC of the battery from at least one of the SOCs.

Other features and aspects will be apparent from the following detailed description, the drawings, and the claims.

### BRIEF DESCRIPTION OF THE DRAWINGS

FIG. 1 is a flowchart illustrating an example of a battery state estimation method.

FIG. 2A illustrates an example of a configuration of a battery.

FIG. 2B illustrates an example of a configuration of a battery.

FIG. 3 is a flowchart illustrating an example of a battery state estimation method.

FIG. 4A illustrates an example of a distribution of states of charge (SOCs).

FIG. 4B illustrates an example of a distribution of SOCs.

FIG. 4C illustrates an example of a distribution of SOCs.

FIG. 4D illustrates an example of a distribution of SOCs.

FIG. 5 illustrates an example of a weight function.

FIG. 6 is a block diagram illustrating an example of a configuration of a battery state estimation apparatus.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

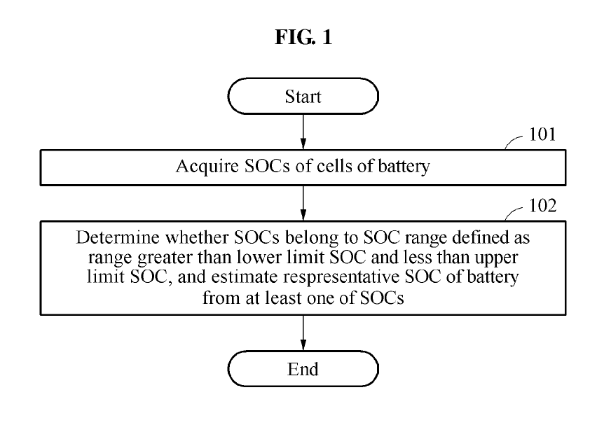

FIG. 1 illustrates an example of a battery state estimation method.

Referring to FIG. 1, in operation 101, a battery state estimation apparatus acquires states of charge (SOCs) of cells of a battery. Here, acquiring the SOCs of cells of the battery includes a concept of directly measuring or estimating an SOC of a cell or acquiring a measured or estimated SOC. The battery includes a charger or a secondary cell configured to store power by charging and a device to which the battery is mounted may supply the power from the battery to a load. The load is an entity that consumes the power and may supply the power supplied from an outside. In an example, the load includes an electric heater, a light, a motor of an electric vehicle, and the like, that consume power using circuits in which current flow at a specific voltage.

The battery state estimation apparatus is an apparatus that estimates a state of the battery, and may be configured as a software module, a hardware module, or a combination thereof. For example, the battery state estimation apparatus may be configured by a battery management system (BMS). The BMS is a system that manages the battery, and, for example, may monitor the state of the battery, maintain an optimal condition for an operation of the battery, predict a replacement timing of the battery, detect a fault of the battery, generate a control signal or a command signal associated with the battery, and control the state or the operation of the battery.

The battery state estimation apparatus estimates an SOC of a cell of the battery based on current and voltage of the cell of the battery. The SOC is a parameter that indicates a charging state of the battery. The SOC indicates a level of energy stored in the battery and an amount of SOC may be indicated as 0 to 100% using a percentage unit. For example, 0% indicates a completely discharged state and 100% indicates a fully charged state. This representation method may be variously modified and defined based on the design intent or example embodiments. A variety of methods may be employed when the battery state estimation apparatus estimates the SOC.

The battery includes cells. Here, a cell is a unit of a device or a constituent element that stores the power. For example, the battery may include cells aligned in series or in parallel. The battery may include modules. The modules may be aligned in series or in parallel and a module may include a set of cells.

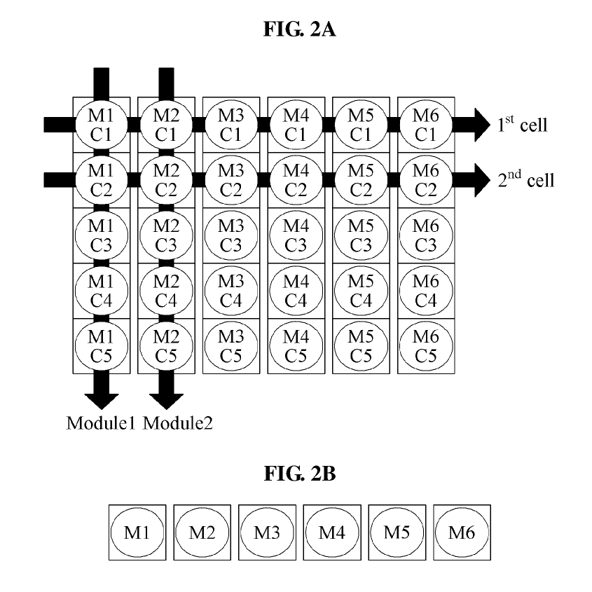

FIG. 2A illustrates an example of a configuration of a battery, and FIG. 2B illustrates an example of a configuration of a battery.

Referring to FIG. 2A, the battery includes a first module M1 through a sixth module M6. Each module includes a first cell C1 to a fifth cell C5. The battery includes 5×6 cells. Referring to FIG. 2B, the battery may be represented as a set of modules M1 to M6 each representing cells.

Here, the battery of which the state is to be estimated may include at least one of a battery pack that includes a plurality of battery modules, at least one battery module in the battery pack, a battery module that includes a plurality of battery cells, at least one battery cell in the battery module, a representative module that represents a plurality of battery modules, and a representative cell that represents a plurality of battery cells. Hereinafter, the battery may be interpreted to indicate the above examples.

Referring again to FIG. 1, in operation 102, the battery state estimation apparatus determines whether the SOCs are within an SOC range defined as a range greater than a lower limit SOC and less than an upper limit SOC, and estimates a representative SOC of the battery from at least one of the SOCs. Here, the SOC range defined as the range greater than the lower limit SOC and less than the upper limit SOC is referred to as a safe range. For example, the safe range may be set as a range from X % of the lower limit SOC to Y % of the upper limit SOC, where X and Y are an integers. An SOC range defined as a range less than the lower limit SOC is referred to as a lower risk range. For example, the lower risk range may be set as a range from 0% to X % of the lower limit SOC. An SOC range defined as a range greater than the upper limit SOC is referred to as an upper risk range. For example, the upper risk range may be set as a range from Y % of the upper limit SOC to 100%, where Y is an integer. A representative SOC of the battery is a parameter that indicates the state of the battery, and is a value that represents the SOC of the battery including cells. Hereinafter, an example of estimating the representative SOC based on SOCs of cells of the battery is described. The example may be applicable to an operation of estimating the representative SOC based on SOCs of modules of the battery and may be applicable to an operation of estimating the representative SOC based on an SOC of at least one cell or an SOC of at least one module. The example is not limited to an aspect of cells or modules.

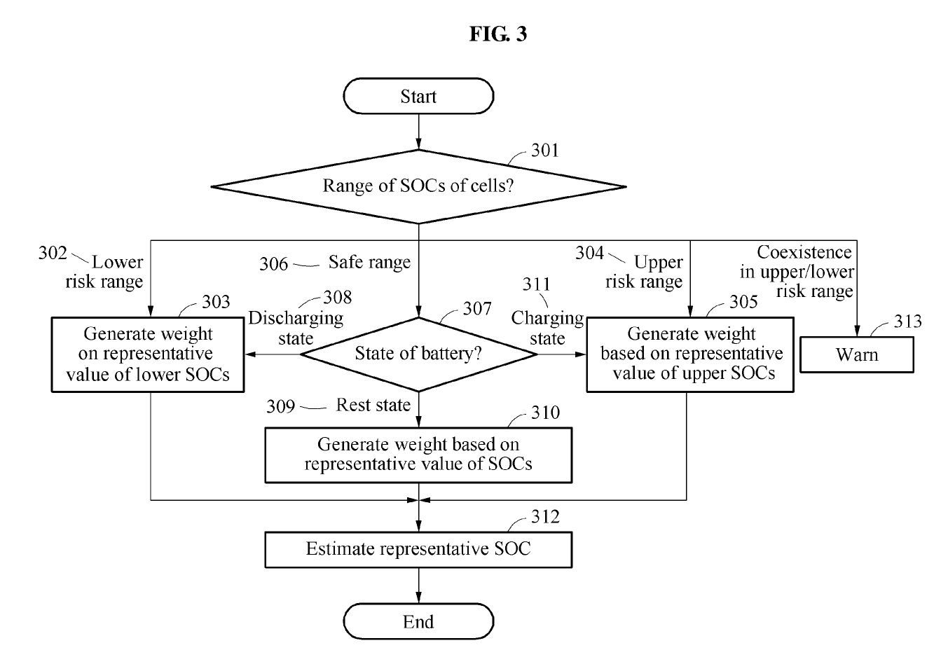

FIG. 3 illustrates a battery state estimation method.

Referring to FIG. 3, in operation 301, a battery state estimation apparatus determines a range to which SOCs of cells of a battery belong. The range includes the aforementioned safe range, lower risk range, and upper risk limit.

In operation 302, the battery state estimation apparatus determines whether at least one of the SOCs of the cells belongs to the lower risk range. If at least one of the SOCs of the cells is less than a lower limit SOC, the battery state estimation apparatus may process an operation or a command corresponding to the lower risk range.

If at least one of the SOCs of the cells belongs to the lower risk range, the battery state estimation apparatus generates a weight based on a representative value of lower SOCs of a predetermined ratio, among the SOCs, of the cells in operation 303. Here, the lower SOCs of the predetermined ratio denote SOCs that are included in a lower ratio among the SOCs. The lower ratio may be the bottom 20%. The lower SOCs of the predetermined ratio are referred to as at-risk SOCs.

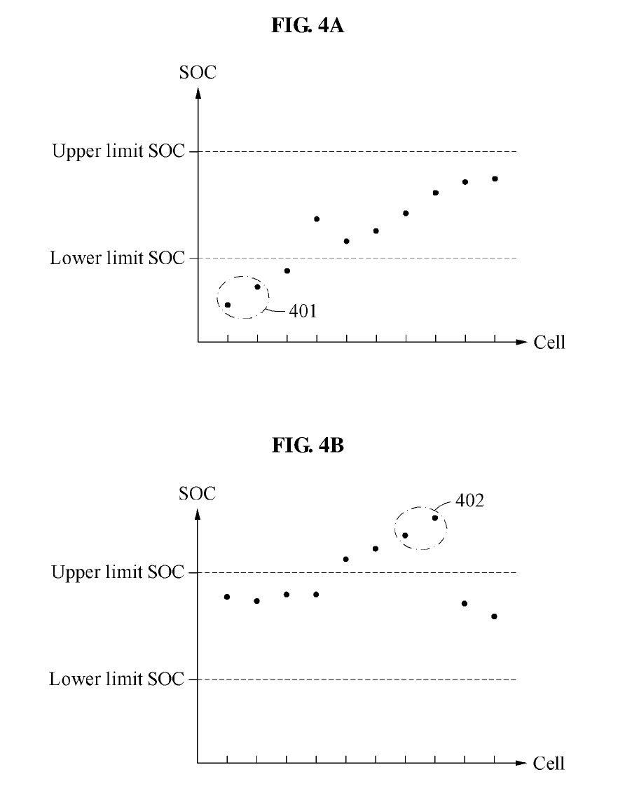

FIG. 4A illustrates an example of a distribution of SOCs. Referring to FIG. 4, if at least one of SOCs of cells belongs to the lower risk range, the battery state estimation apparatus generates the weight based on lower SOCs 401 of the predetermined ratio, for example, bottom 20%, among the SOCs of the cells. Here, at-risk SOCs correspond to the lower SOCs 401.

In one example, the battery state estimation apparatus generates a weight for estimating a representative SOC based on at least one of a statistical characteristic of SOCs of cells, a statistical characteristic of temperatures of the cells, and a representative value of the lower SOCs 401. The statistical characteristic of the SOCs of the cells includes a standard deviation of the SOCs of the cells, the statistical characteristic of the temperatures of the cells includes a standard deviation of the temperatures of the cells, and the representative value of the lower SOCs 401 includes an average of the lower SOCs 401, that is, the at-risk SOCs. The battery state estimation apparatus generates the weight according to Equation 1.

$$W = \frac{1}{2} ( 1 + tan h ( {exp}^{a + b \cdot σ {soc}_{i} + c \cdot σ r} • ( {SOC}_{RISK}^{- 50} ) ) ) \qquad [ Equation 1 ]$$

In Equation 1, w denotes the weight, each of a, b, and c denotes a constant, SOCᵢ denotes SOCs of all of the cells, σSOCᵢ denotes a standard deviation of the SOCs of the cells, σ_{T} denotes a standard deviation of temperatures of the cells, and SOCᵣᵢₛₖ denotes a representative value, for example, average, of the at-risk SOCs.

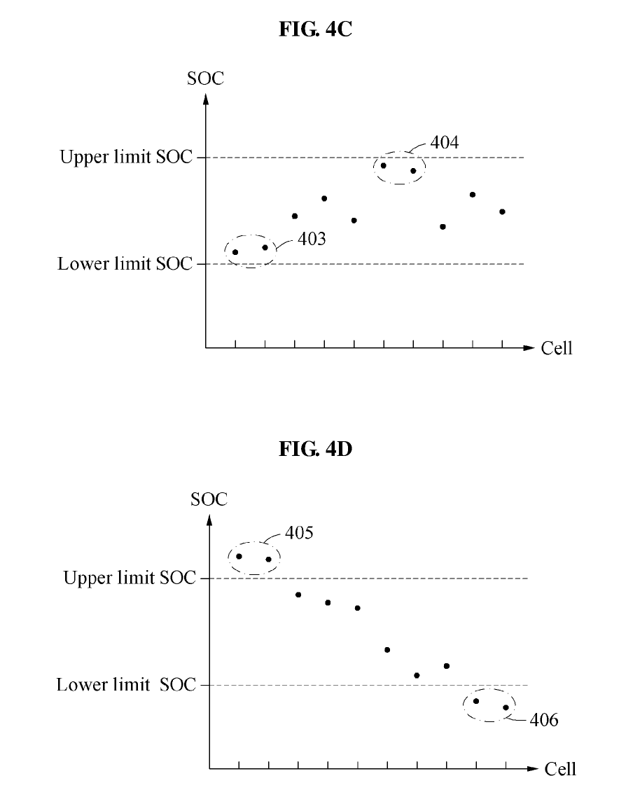

If a deviation of the SOCs or the temperatures of the cells is relatively great, the battery state estimation apparatus generates the weight so that the weight is applied to a maximum value or a minimum value of the SOCs of the cells. Referring to FIG. 5, the weight w according to Equation 1 is represented based on SOCᵣᵢₛₖ. FIG. 5 is a graph in which x axis denotes SOCᵣᵢₛₖ and y axis denotes w. Based on an increase in σSOCᵢ or σ_{T}, the slope of w in response to Equation 1 becomes steeper. As the graph becomes steeper in shape, a relatively great weight is applied to a maximum value or a minimum value of the SOCs. Using Equation 1, the battery state estimation apparatus generates the weight so that a relatively great weight is applied to the maximum value or the minimum value of the SOCs based on an increase in σSOCᵢ or σ_{T}. Thus, the battery state estimation apparatus estimates the representative SOC for preventing a risk of over-discharging or overcharging using the generated weight. The battery state estimation apparatus applies the standard deviation of SOCs of the cells or the standard deviation of temperatures of the cells to a weight function and estimates the representative SOC to which a deviation of the SOCs or a deviation of the temperatures is applied. The representative SOC to which the deviation of SOCs or the deviation of temperatures is applied is estimated by applying the relatively great weight to the maximum value or the minimum value of SOCs of the cells. Thus, the battery state estimation apparatus controls the battery using the estimated representative SOC so that over-discharging or overcharging does not occur.

In operation 312, the battery state estimation apparatus estimates the representative SOC by applying the weight to a maximum SOC and a minimum SOC among the SOCs of the cells. The battery state estimation apparatus estimates the representative SOC based on Equation 2.

SOCₚ=w·max(SOCᵢ)+(1−w)·min(SOCᵢ) [Equation 2]

In Equation 2, SOCₚ denotes the representative SOC, w denotes the weight, SOCᵢ denotes SOCs of all of the cells, max(SOCᵢ) denotes the maximum SOC among the SOCs, and min(SOCᵢ) denotes the minimum SOC among the SOCs. The battery state estimation apparatus prevents over-discharging or overcharging by assigning a relatively great weight to the maximum value or the minimum value of the SOCs. The method of estimating the representative SOC is provided as an example only and a variety of methods of estimating the representative SOC may be applied based on the weight generated according to an example.

In operation 304, the battery state estimation apparatus determines whether at least one of the SOCs of the cells belongs to an upper risk range. If at least one of the SOCs of the cells is less than an upper limit SOC, the battery state estimation apparatus processes an operation or a command corresponding to the upper risk range.

If at least one of the SOCs of the cells belongs to the upper risk range, the battery state estimation apparatus generates the weight based on a representative value of upper SOCs of a predetermined ratio, among the SOCs, of the cells in operation 305. Here, the upper SOCs of the predetermined ratio denote SOCs that are included in an upper ratio among the SOCs. The upper ratio is defined to be variously applied based on the design intent. For example, the upper ratio may be the top 20%. The upper SOCs of the predetermined ratio may be referred to as at-risk SOCs.

FIG. 4B illustrates an example of a distribution of SOCs. Referring to FIG. 4B, if at least one of SOCs of cells belongs to the upper risk range, the battery state estimation apparatus generates the weight based on upper SOCs 402 of the predetermined ratio, for example, the top 20%, among the SOCs of the cells. Here, at-risk SOCs correspond to the upper SOCs 402.

In one example, the battery state estimation apparatus generates a weight for estimating a representative SOC based on at least one of a statistical characteristic of SOCs of cells, a statistical characteristic of temperatures of the cells, and a representative value of the upper SOCs 402. As described above, the statistical characteristic of the SOCs of the cells includes a standard deviation of the SOCs of the cells, the statistical characteristic of the temperatures of the cells includes a standard deviation of the temperatures of the cells, and the representative value of the upper SOCs 402 includes an average of the upper SOCs 402, that is, the at-risk SOCs. The battery state estimation apparatus generates the weight according to Equation 1. The aforementioned description is applied to the example of generating the weight.

In operation 312, the battery state estimation apparatus estimates the representative SOC by applying the weight to the maximum SOC and the minimum SOC among the SOCs of the cells. The battery state estimation apparatus estimates the representative SOC based on Equation 2. The aforementioned description is applied to the example of estimating the representative SOC.

In operation 306, the battery state estimation apparatus determines whether all of the SOCs of the cells are within a safe range. If all of the SOCs of the cells are greater than a lower limit SOC and less than an upper limit SOC, the battery state estimation apparatus processes an operation or a command corresponding to the safe range.

If the SOCs are within the safe range, the battery state estimation apparatus determines whether the battery is in a discharging state, a rest state, or a charging state in operation 307. The battery state estimation apparatus determines the state of the battery based on at least one of current and voltage of the battery.

The rest state of the battery includes a state in which charging or discharging of the battery is absent. For example, the rest time includes at least one of a state in which a discharging current or a charging current is zero (0) due to the passing of a predetermined time during an operation of the battery and a state in which the battery is stopped in response to the passing of the predetermined time and then operates.

A previous state of the battery in the rest state indicates a previous battery state before the battery enters in the rest state. The battery state estimation apparatus determines whether the battery is being charged or discharged, that is, whether the battery is in a discharging state or in a charging state before the battery enters into the rest state. For example, if an electric vehicle to which the battery is mounted is currently stopped in front of a stop signal light after driving on the road, the battery state estimation apparatus determines that the battery is in the rest state and determines that the previous state of the battery in the rest state is the discharging state. If the electric vehicle to which the battery is mounted is currently stopped after driving on a downhill road, the battery state estimation apparatus determines that the battery is in the rest state and that the previous state of the battery in the rest state is in the charging state. In the case of driving on the downhill road, the battery may be charged through regenerative braking. If the ignition of the electric vehicle of which battery charging is completed is turned off and then turned on at a charging station, the battery state estimation apparatus determines that the battery is in the rest state and the previous state of the battery in the rest state is the charging state.

In operation 308, the battery state estimation apparatus determines whether the battery is in the discharging state. If the battery of which the SOCs of the cells are within the safe range is in the discharging state, the battery state estimation apparatus may process an operation or a command corresponding to the discharging state.

If the battery is in the discharging state, the battery state estimation apparatus may generate the weight based on the representative value of the lower SOCs of the predetermined ratio, among the SOCs, of the cells in operation 303. The lower SOCs of the predetermined ratio may be referred to as risk SOCs.

FIG. 4C illustrates an example of a distribution of SOCs. Referring to FIG. 4C, if SOCs of cells of a battery in a discharging state are within the safe range, the battery state estimation apparatus may generate the weight based on lower SOCs 403 of a predetermined ratio, for example, bottom 20%, among the SOCs of the cells. Here, risk SOCs may correspond to the lower SOCs 403.

In one example, the battery state estimation apparatus may generate a weight for estimating a representative SOC based on at least one of a statistical characteristic of SOCs of cells, a statistical characteristic of temperatures of the cells, and a representative value of the lower SOCs 403. As described above, the statistical characteristic of the SOCs of the cells includes a standard deviation of the SOCs of the cells, the statistical characteristic of the temperatures of the cells includes a standard deviation of the temperatures of the cells, and the representative value of the lower SOCs 403 includes an average of the lower SOCs 403, that is, the risk SOCs. The battery state estimation apparatus may generate the weight according to Equation 1. The aforementioned description may be applied to the example of generating the weight.

In operation 312, the battery state estimation apparatus estimates the representative SOC by applying the weight to the maximum SOC and the minimum SOC among the SOCs of the cells. The battery state estimation apparatus may estimate the representative SOC according to Equation 2. The aforementioned description may be applied to the example of estimating the representative SOC.

In operation 309, the battery state estimation apparatus determines whether the battery is in the rest state. If the battery of which SOCs of cells belongs to the safe range is in the rest time, the battery state estimation apparatus may process an operation or a command corresponding to the rest state. In operation 310, if the battery is in the rest state, the battery state estimation apparatus generates the weight based on the representative value of the SOCs of the cells.

Referring to FIG. 4C, if SOCs of cells of the battery in the rest state are within the safe range, the battery state estimation apparatus may generate the weight for estimating the representative SOC based on at least one of a statistical characteristic of the SOCs of the cells, a statistical characteristic of temperatures of the cells, and a representative value of the SOCs of the cells. As described above, the statistical characteristic of the SOCs of the cells includes a standard deviation of the SOCs of the cells and the statistical characteristic of the temperatures of the cells includes a standard deviation of the temperatures of the cells. The representative value of the SOCs of the cells includes an average of the SOCs of the cells. The battery state estimation apparatus may generate the weight according to Equation 1. Here, the representative value of the SOCs of the cells may be applied to SOCᵣᵢₛₖ. The aforementioned description may be applied to the example of generating the weight.

In operation 312, the battery state estimation apparatus estimates the representative SOC by applying the weight to the maximum SOC and the minimum SOC among the SOCs of the cells. The battery state estimation apparatus may estimate the representative SOC according to Equation 2. The aforementioned description may be applied to the example of estimating the representative SOC.

In operation 311, the battery state estimation apparatus determines whether the battery is in the charging state. If the battery of which the SOCs of the cells are within the safe range is in the charging state, the battery state estimation apparatus may process an operation or a command corresponding to the charging state.

If the battery is in the charging state, the battery state estimation apparatus generates the weight based on a representative value of upper SOCs of the predetermined ratio, among the SOCs, of the cells in operation 305. As described above, the upper SOCs of the predetermined ratio may be referred to as risk SOCs.

Referring to FIG. 4C, if SOCs of cells of the battery in the charging state are within the safe range, the battery state estimation apparatus may generate the weight based on upper SOCs 404 of the predetermined ratio, for example, top 20%, among the SOCs of the cells. Here, risk SOCs may correspond to the upper SOCs 404.

In one example, the battery state estimation apparatus may generate a weight for estimating a representative SOC based on at least one of a statistical characteristic of SOCs of cells, a statistical characteristic of temperatures of the cells, and a representative value of the upper SOCs 404. As described above, the statistical characteristic of the SOCs of the cells includes a standard deviation of the SOCs of the cells, the statistical characteristic of the temperatures of the cells includes a standard deviation of the temperatures of the cells, and the representative value of the upper SOCs 404 includes an average of the upper SOCs 404, that is, the risk SOCs. The battery state estimation apparatus may generate the weight according to Equation 1. The aforementioned description may be applied to the example of generating the weight.

In operation 312, the battery state estimation apparatus estimates the representative SOC by applying the weight to the maximum SOC and the minimum SOC among the SOCs of the cells. The battery state estimation apparatus may estimate the representative SOC according to Equation 2. The aforementioned description may be applied to the example of estimating the representative SOC.

The battery state estimation apparatus may determine whether SOCs of cells coexist in the upper risk range and the lower risk range. If at least one of the SOCs of the cells is greater than the upper limit SOC and at least one of the SOCs of the cells is less than the lower limit SOC, the battery state estimation apparatus may process an operation or a command corresponding to the coexistence in the upper risk range and the lower risk range.

FIG. 4D illustrates an example of a distribution of SOCs. Referring to FIG. 4D, if at least one, for example, SOCs 405, of SOCs of cells is greater than the upper limit SOC and at least one, for example, SOCs 406, of the SOCs of the cells is less than the lower limit SOC, the battery state estimation apparatus may detect a malfunction of the battery. In operation 313, the battery state estimation apparatus detects the malfunction of the battery and notifies the detected malfunction.

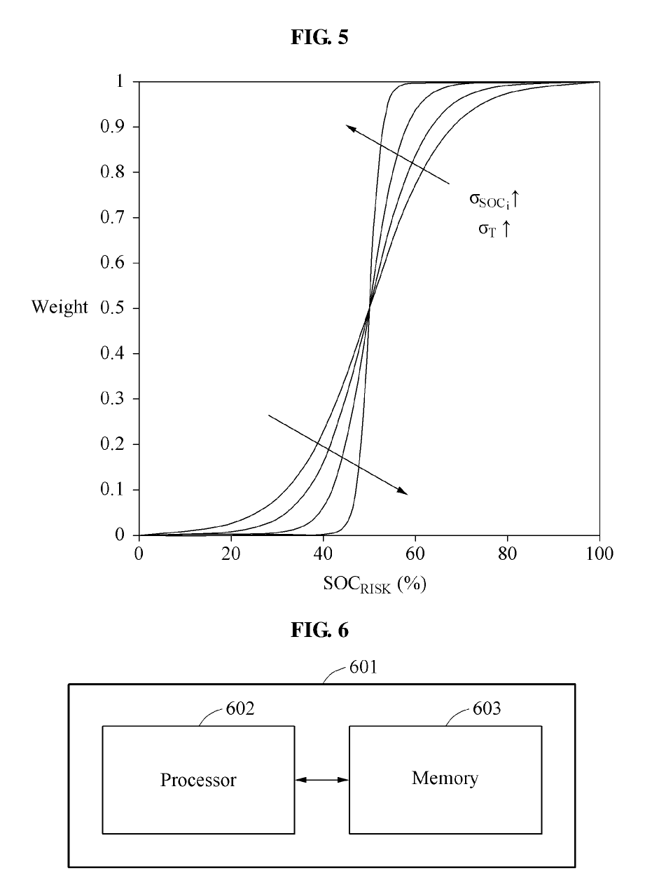

FIG. 6 illustrates an example of a configuration of a battery state estimation apparatus.

Referring to FIG. 6, a battery state estimation apparatus 601 includes a processor 602 and a memory 603. The processor 602 may include one or more of the apparatuses described with FIGS. 1 through 5, or may perform one or more of the methods described with FIGS. 1 through 5. The memory 603 stores a program in which the battery state estimation method is configured. The memory 603 may be a volatile memory or a nonvolatile memory.

The processor 602 executes the program and controls the battery state estimation apparatus 601. A code of the program executed by the processor 602 may be stored in the memory 603. The battery state estimation apparatus 601 may be connected to an external device, for example, a personal computer (PC) or a network, through an input/output (I/O) device (not shown) and may exchange data.

The processor in FIGS. 1-6 that perform the operations described in this application are implemented by hardware components configured to perform the operations described in this application that are performed by the hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1 and 3 that perform the operations described in this application are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A method of estimating a battery state, comprising:
acquiring states of charge (SOCs) of cells of a battery; and
determining whether the SOCs are within an SOC range defined as a range greater than a lower limit SOC and less than an upper limit SOC, and estimating a representative SOC of the battery from at least one of the SOCs.

2. The method of claim 1, wherein the estimating comprises:
estimating the representative SOC based on lower SOCs of a predetermined ratio, among the SOCs, in response to at least one of the SOCs being less than the lower limit SOC.

3. The method of claim 2, wherein the estimating based on the lower SOCs comprises:
generating a weight for estimating the representative SOC based on any one or any combination of a statistical characteristic of the SOCs, a statistical characteristic of temperatures of the cells, and a representative value of the lower SOCs; and
estimating the representative SOC by applying the weight to a maximum SOC and a minimum SOC among the SOCs.

4. The method of claim 1, wherein the estimating comprises:
estimating the representative SOC based on upper SOCs of a predetermined ratio, among the SOCs, in response to at least one of the SOCs being greater than the upper limit SOC.

5. The method of claim 4, wherein the estimating based on the upper SOCs comprises:
generating a weight for estimating the representative SOC based on any one or any combination of a statistical characteristic of the SOCs, a statistical characteristic of temperatures of the cells, and a representative value of the upper SOCs; and
estimating the representative SOC by applying the weight to a maximum SOC and a minimum SOC among the SOCs.

6. The method of claim 1, wherein the estimating comprises:
determining whether the battery is in a discharging state, a rest state, or a charging state, in response to the SOCs being within the SOC range;
generating a weight for estimating the representative SOC based on a result of the determining whether the battery is in the discharging state, the rest state, or the charging state; and
estimating the representative SOC by applying the weight to a maximum SOC and a minimum SOC among the SOCs.

7. The method of claim 6, wherein the generating comprises:
generating the weight based on any one or any combination of a statistical characteristic of the SOCs, a statistical characteristic of temperatures of the cells, and a representative value of lower SOCs of a predetermined ratio, among the SOCs, in response to the battery being in the discharging state.

8. The method of claim 6, wherein the generating comprises:
generating the weight based on any one or any combination of a statistical characteristic of the SOCs, a statistical characteristic of temperatures of the cells, and a representative value of the SOCs, in response to the battery being in the rest state.

9. The method of claim 6, wherein the generating comprises:
generating the weight based on any one or any combination of a statistical characteristic of the SOCs, a statistical characteristic of temperatures of the cells, and a representative value of upper SOCs of a predetermined ratio, among the SOCs, in response to the battery being in the charging state.

10. The method of claim 1, wherein the estimating comprises:
detecting a malfunction of the battery in response to at least one of the SOCs being greater than the upper limit SOC and at least one of the SOCs being less than the lower limit SOC.

11. A method of estimating a battery state, comprising:
acquiring states of charge (SOCs) of cells of a battery;
acquiring temperatures of the cells;
generating a weight based on at least one of a statistical characteristic of the SOCs and a statistical characteristic of the temperatures; and
estimating a representative SOC of the battery based on the SOCs and the weight.

12. The method of claim 11, wherein the statistical characteristic of the SOCs comprises a standard deviation of the SOCs, and
the statistical characteristic of the temperatures comprises a standard deviation of the temperatures.

13. The method of claim 11, wherein the generating comprises:
determining whether the SOCs are within an SOC range defined as a range greater than a lower limit SOC and greater than an upper limit SOC; and
generating the weight based on a result of the determining whether the SOCs are within the SOC range.

14. The method of claim 13, wherein the generating based on the result of the determining comprises:
determining whether the battery is in a discharging state, a rest state, or a charging state, in response to the SOCs being within the SOC range;
generating the weight based on any one or any combination of a statistical characteristic of the SOCs, a statistical characteristic of temperatures of the cells, and a representative value of lower SOCs of a predetermined ratio, among the SOCs, in response to the battery being in the discharging state;
generating the weight based on any one or any combination of the statistical characteristic of the SOCs, the statistical characteristic of temperatures of the cells, and the representative value of the SOCs, in response to the battery being in the rest state; and
generating the weight based on any one or any combination of the statistical characteristic of the SOCs, the statistical characteristic of temperatures of the cells, and the representative value of upper SOCs of a predetermined ratio, among the SOCs, in response to the battery being in the charging state.

15. The method of claim 13, wherein the generating based on the result of the determining comprises:
generating the weight based on any one or any combination of a statistical characteristic of the SOCs, a statistical characteristic of temperatures of the cells, and a representative value of lower SOCs of a predetermined ratio, among the SOCs, in response to at least one of the SOCs being less than the lower limit SOC.

16. The method of claim 13, wherein the generating based on the result of the determining comprises:
generating the weight based on any one or any combination of a statistical characteristic of the SOCs, a statistical characteristic of temperatures of the cells, and a representative value of upper SOCs of a predetermined ratio, among the SOCs, in response to at least one of the SOCs being greater than the upper limit SOC.

17. A non-transitory computer-readable medium storing a computer program to implement the method of claim 1.

18. A battery state estimation apparatus, comprising:
a processor configured to:
acquire states of charge (SOCs) of cells of a battery;
determine whether the SOCs are within an SOC range defined as a range greater than a lower limit SOC and less than an upper limit SOC; and
estimate a representative SOC of the battery from at least one of the SOCs.

19. The battery state estimation apparatus of claim 18, wherein the processor is further configured to:
determine whether the battery is in a discharging state, a rest state, or a charging state, in response to the SOCs being within the SOC range;
generate a weight for estimating the representative SOC based on a result of the determining whether the battery is in the discharging state, the rest state, or the charging state; and
estimate the representative SOC by applying the weight to a maximum SOC and a minimum SOC among the SOCs.

20. The battery state estimation apparatus of claim 19, wherein the processor is further configured to:
generate the weight based on any one or any combination of a statistical characteristic of the SOCs, a statistical characteristic of temperatures of the cells, and a representative value of lower SOCs of a predetermined ratio, among the SOCs, in response to the battery being in the discharging state;
generate the weight based on any one or any combination of the statistical characteristic of the SOCs, the statistical characteristic of temperatures of the cells, and the representative value of the SOCs, in response to the battery being in the rest state; and
generate the weight based on any one or any combination of the statistical characteristic of the SOCs, the statistical characteristic of temperatures of the cells, and the representative value of upper SOCs of a predetermined ratio, among the SOCs, in response to the battery being in the charging state.
